(19) United States
(12) Patent Application Publication
(10) Pub. No.: US 2013/0292096 A1
(43) Pub. Date: Nov. 7, 2013

(54) HEAT DISSIPATING FAN AND FAN WHEEL

(71) Applicant: Wei-Cheng HUNG, New Taipei City (TW)

(72) Inventor: Wei-Cheng HUNG, New Taipei City (TW)

(73) Assignee: SilverStone Technology Co., Ltd.

(21) Appl. No.: 13/463,150

(22) Filed: May 3, 2012

(51) Int. Cl. H01L 23/467; B64C 11/04

(52) U.S. Cl. 165/121; 416/204 R

(57) ABSTRACT

A fan wheel comprises an axial line, a radial line perpendicular to the axial line, a first vane and a second vane, and the first vane and the second vane are extended from the axial line, and included angles between chord lines of the first and second vanes and the axial line of the fan wheel are unequal angles. A heat dissipating fan comprises a fan hub, a plurality of first vanes and a plurality of second vanes, and the first vanes and the second vanes are extended outwardly from the fan hub, and excluded angles between their chord lines and the axial line of the fan hub are unequal angles.

### FIELD OF THE INVENTION

The present invention relates to a heat dissipating fan, in particular to the heat dissipating fan having vanes arranged with different included angles.

### BACKGROUND OF THE INVENTION

In general, computer chips generate heat during their operation. For example, electronic products such as mobile phones with a slower computing speed still can dissipate the generated heat to the air by natural convection, but the heat generated by present existing computer chips with a high computing speed no longer can be dissipated to the air by the natural convection completely, so that fans are usually installed in a computer casing to perform a compulsory convection.

The selection of fans is evaluated according to system structure and heat dissipation requirements of a computer. In other words, the heat dissipating fans are usually selected by taking the flow impedance of the system into consideration. However, airflow and wind pressure of the heat dissipating fan cannot be taken into consideration concurrently, and the correlation between the airflow and the wind pressure of the fan relates to the angle of inclination of vanes with respect to the axial line of an axle. The greater the angle of inclination of the vanes with respect to the axial line of the axle, the greater is the wind pressure of the fan and the smaller is the airflow. On the other hand, the smaller the angle of inclination of the vanes with respect to the axial line of the axle, the greater is the airflow and the smaller is the wind pressure.

Therefore, a fan with a greater airflow can be selected in an environment with a smaller flow impedance, and a fan with a greater wind pressure can be selected in an environment with a greater flow impedance (such as a cotton filter or a filter that is additionally installed onto an air inlet or an air outlet of a casing) to overcome the problem of the flow impedance. Since different casing structures require different fans, inappropriate fans may be installed by mistake easily and result in poor heat dissipation, and manufacturers need to manufacture fans with different specifications to cope with different requirements, thus incurring a higher cost.

In view of the foregoing problem of the prior art, the inventor of the present invention conducts extensive researches and experiments, and finally provided a feasible design to overcome the problem.

### SUMMARY OF THE INVENTION

Therefore, it is a primary objective of the present invention to provide a fan wheel of a heat dissipating fan having vanes installed at different angles of inclination to fit the installing environment of various different flow impedances.

To achieve the aforementioned objective, the present invention provides a fan wheel, comprising an axial line, a radial line perpendicular to the axial line, a first vane and a second vane, wherein the first vane is extended along the radial line, and a first included angle is defined between a chord line of the first vane and the axial line, and the second vane is extended along the radial line, and a second included angle is defined between a chord line of the second vane and the axial line, and the second included angle and the first included angle are unequal angles.

Preferably, the fan wheel further comprises a third vane extended along the radial line, and a third included angle is defined between a chord line of the third vane and the axial line, wherein the third included angle, the second included angle, and the first included angle are unequal angles.

Preferably, the first vanes of the fan wheel are installed uniformly in a circumferential direction of the axial line.

Preferably, the second vanes of the fan wheel are installed uniformly in a circumferential direction of the axial line.

To achieve the aforementioned objective, the present invention provides another fan wheel, comprising a fan hub, a first vane and a second vane. The fan hub has an axial line and a radial line perpendicular to the axial line. The first vane is extended in a radial direction and outwardly from the periphery of the fan hub, and a first included angle is defined between a chord line of the first vane and the axial line of the fan hub. The second vane is extended in a radial direction and outwardly from the periphery of the fan hub, and a second included angle is defined between a chord line of the second vane and the axial line of the fan hub, and the second included angle and the first included angle are unequal angles.

Preferably, the first vane and the second vane of the fan wheel are integrally formed at fan hub.

Preferably, the fan wheel further comprises a third vane extended along the radial line and outwardly from the periphery of the fan hub, and a third included angle is defined between a chord line of the third vane and the axial line of the fan hub, wherein the third included angle, the second included angle, and the first included angle are unequal angles.

Another objective of the present invention is to provide a heat dissipating fan having vanes installed at different angles of inclination to fit installing environments of various different flow impedances.

To achieve the aforementioned objective, the present invention provides a heat dissipating fan comprising a fan hub, a plurality of first vanes and a plurality of second vanes. The fan hub is a cylindrical body having an axial line and a radial line perpendicular to the axial line. The first vanes are extended along the radial line and outwardly from the periphery of the fan hub, and a first included angle is defined between a chord line of each first vane and the axial line of the fan hub. The second vanes are extended along the radial line and outwardly from the periphery of the fan hub, and a second included angle is defined between a chord line of each second vane and the axial line of the fan hub, and each second included angle and each first included angle are unequal angles.

Preferably, the first vanes of the heat dissipating fan are installed uniformly along the axial line.

Preferably, the second vanes of the heat dissipating fan are installed uniformly along the axial line.

Preferably, the first vane and the second vane of the heat dissipating fan are integrally formed at the fan hub.

Preferably, the heat dissipating fan further comprises a plurality of third vanes extended along the radial one and outwardly from the periphery of the fan hub, and a third included angle is defined between a chord line of each third vane and the axial line, and each second included angle, each first included angle and each second included angle are unequal angles.

Preferably, the heat dissipating fan further comprises a frame, and the fan hub is installed on an internal side of the frame.

Since the vanes of the heat dissipating fan of the present invention are installed at different angles of inclination, therefore the vanes with a fixed proportion can maximize their working efficiency at different flow impedances, and the heat dissipating fan of the present invention can fit various different flow impedances.

### BRIEF DESCRIPTION OF THE DRAWINGS

FIG. 1 is a perspective view of a heat dissipating fan in accordance with a first preferred embodiment of the present invention;

FIG. 2 is an exploded view of a heat dissipating fan in accordance with the first preferred embodiment of the present invention;

FIG. 3 is a schematic view of vanes installed in a fan wheel in accordance with the first preferred embodiment of the present invention;

FIG. 4 is a side view of a first vane of a fan wheel in accordance with the first preferred embodiment of the present invention;

FIG. 5 is a side view of a second vane of a fan wheel in accordance with the first preferred embodiment of the present invention;

FIG. 6 is a schematic view of vanes installed in a fan wheel in accordance with a second preferred embodiment of the present invention;

FIG. 7 is a side view of a third vane of a fan wheel in accordance with the second preferred embodiment of the present invention;

FIG. 8 is a schematic view of vanes installed in a fan wheel in accordance with a third preferred embodiment of the present invention; and

FIG. 9 is a schematic view of vanes installed in a fan wheel in accordance with a fourth preferred embodiment of the present invention.

### DESCRIPTION OF THE PREFERRED EMBODIMENTS

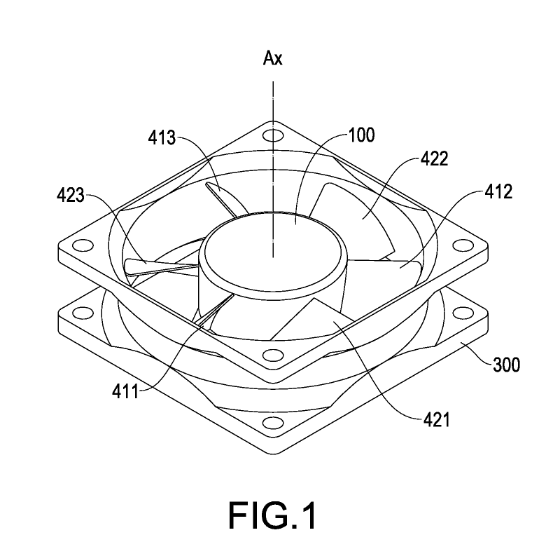

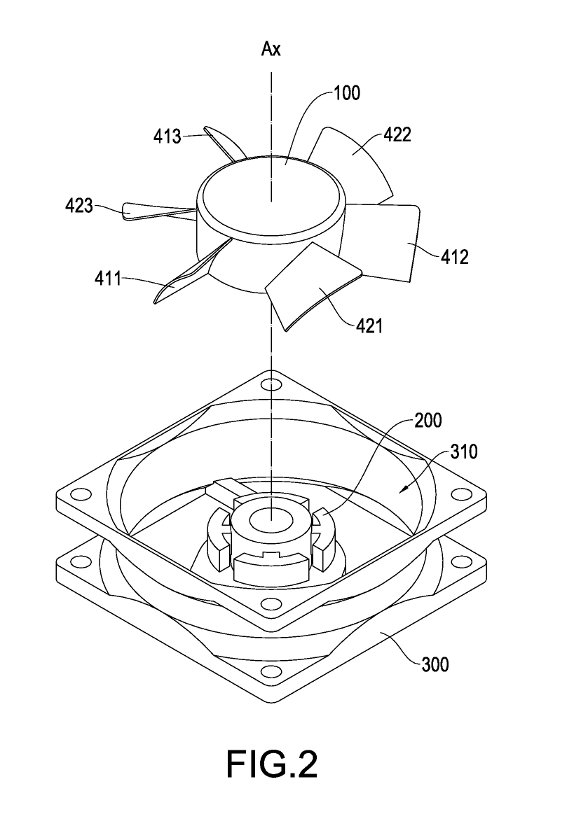

With reference to FIGS. 1 and 2 for a perspective view and an exploded view of a heat dissipating fan in accordance with the first preferred embodiment of the present invention respectively, the heat dissipating fan comprises a fan wheel, a drive motor (200), and a frame (300). The fan wheel comprises a fan hub (100), a plurality of first vanes (411, 412, 413) and a plurality of second vanes (421, 422, 423).

Preferably, the fan hub (100) is made of plastic and in a circular cylindrical shape. The frame (300) is made of plastic and in a square shape having a penetrating circular containing space (310). The drive motor (200) is mounted onto the frame (300) and disposed at the center of the circular containing space (310), and the fan hub (100) is sheathed on the drive motor (200), and the drive motor (200) is used for driving the fan hub (100) to rotate along an axial line (AX).

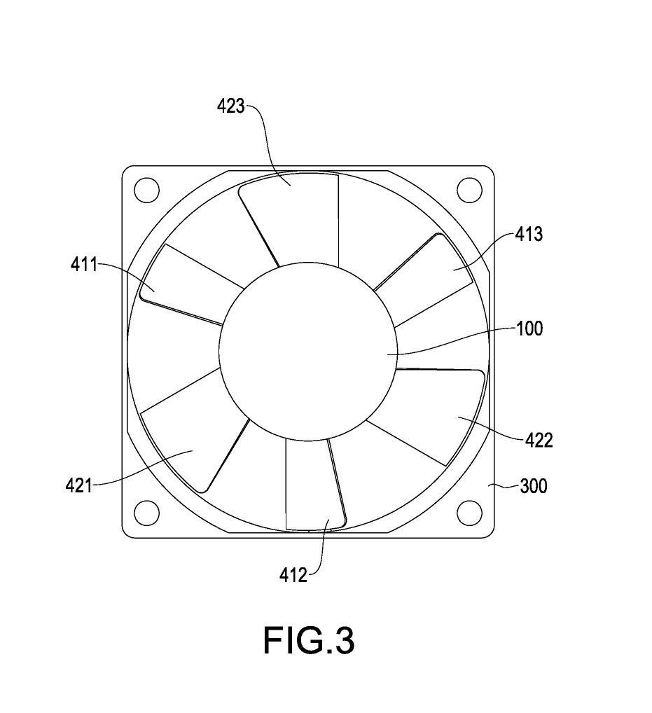

With reference to FIGS. 2 and 3, the fan wheel of this preferred embodiment comprises three first vanes (411, 412, 413) integrally formed at the fan hub (100), and each first vane 411 (412, 413) is extended outwardly from the fan hub (100) in a radial direction of the axial line (AX). The three first vanes (411, 412, 413) are installed uniformly along the circumferential direction of the axial line (AX), and a same first included angle (A1) is defined between each first vane 411 (412, 413) and the axial line (AX), wherein the first included angle (A1) is preferably an acute angle.

In this preferred embodiment, the heat dissipating fan of the present invention preferably comprises three second vanes (421, 422, 423) integrally formed at the fan hub (100), and each second vane 421 (422, 423) is extended in a radial direction of the axial line (AX) and outwardly from the fan hub (100). The three second vanes (421, 422, 423) are installed uniformly in a circumferential direction of the axial line (AX), and a same second included angle (A2) is defined between each second vane 421 (422, 423) and the axial line (AX), wherein the second included angle (A2) is preferably an acute angle.

In this preferred embodiment, the first vanes (411, 412, 413) and the second vanes (421, 422, 423) have the same appearance, and the three first vanes (411, 412, 413) are installed with the same first included angle (A1), and the three second vanes (421, 422, 423) are installed with the same second included angle (A2). The fan hub (100) can be rotated to drive the first vanes (411, 412, 413) and the second vanes (421, 422, 423) to rotate accordingly.

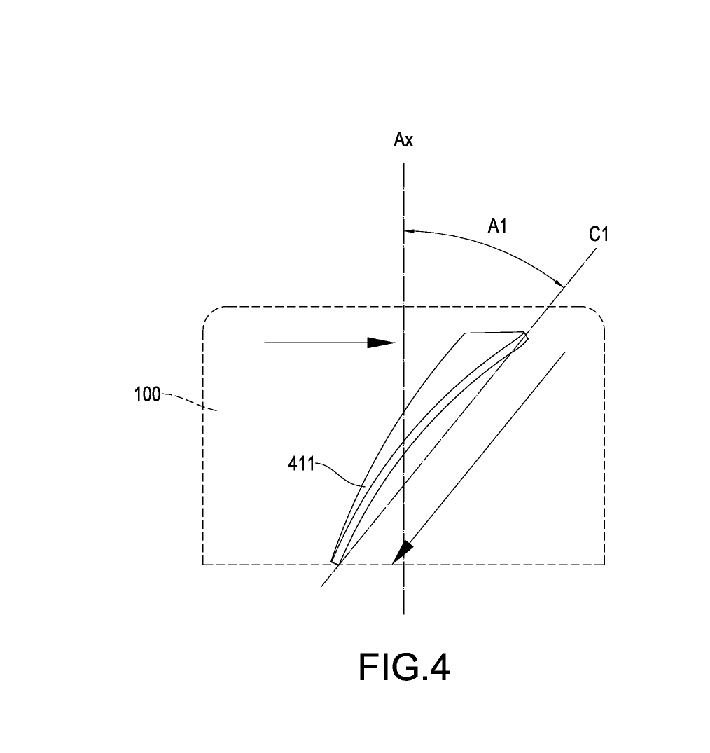

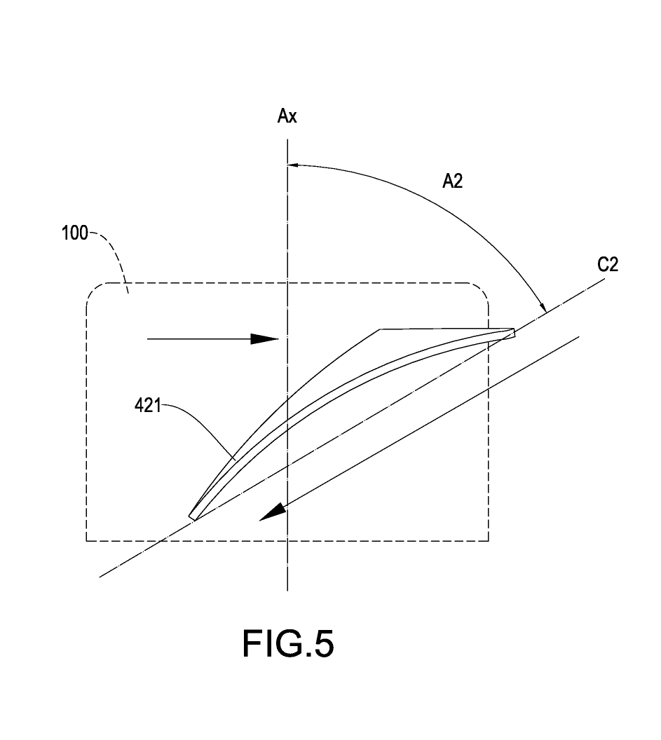

With reference to FIG. 4, a same first included angle A is defined between a chord line (C1) of each first vane 411 (412, 413) and the axial line (AX). With reference to FIG. 5, a same second included angle (A2) is defined between a chord line (C2) of each second vane 421 (422, 423) and the axial line (AX). Preferably, the first included angle (A1) of the first vane is smaller than the second included angle (A2) of the second vane. When the fan hub (100) drives the first vanes (411, 412, 413) and the second vanes (421, 422, 423) to rotate, the three first vanes (411, 412, 413) provide a greater airflow in an environment with a smaller flow impedance and the three second vanes (421, 422, 423) provides a higher wind pressure in an environment with a higher flow impedance.

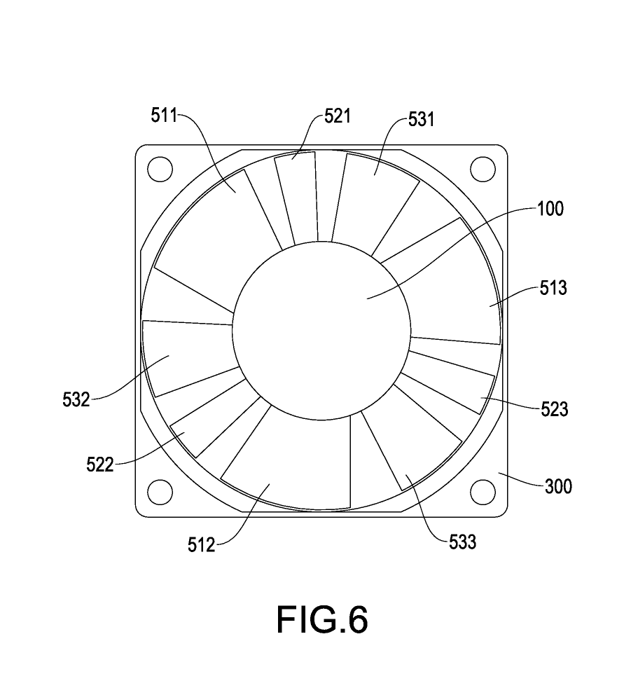

With reference to FIG. 6 for a heat dissipating fan in accordance with the second preferred embodiment of the present invention, the heat dissipating fan comprises a fan wheel, a drive motor (200) and a frame (300). The fan wheel comprises a fan hub (100), a plurality of first vanes (511, 512, 513), a plurality of second vanes (521, 522, 523) and a plurality of third vanes (531, 532, 533). Wherein, the fan hub (100), the drive motor (200) and the frame (300) have the same structure and relation as those of the first preferred embodiment, and thus will not be repeated.

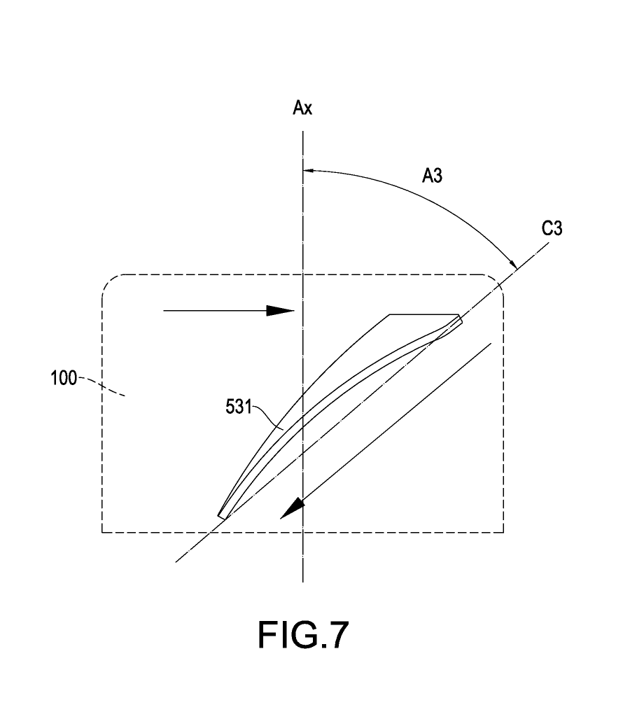

In this preferred embodiment, the heat dissipating fan of the present invention preferably comprises three first vanes (511, 512, 513) uniformly installed in a circumferential direction of the axial line (AX), three second vanes (521, 522, 523) uniformly installed in a circumferential direction of the axial line (AX), and three third vanes (531, 532, 533) uniformly installed in a circumferential direction of the axial line, wherein the first vanes (511, 512, 513), the second vanes (521, 522, 523) and the third vanes (531, 532, 533) preferably have the same appearance and are integrally formed at the fan hub (100) and extended outwardly from the fan hub (100) and in a radial direction of the axial line (AX). A same first included angle (A1) is defined between a chord line (C1) (which is a line defined on a cross-section and connecting front and rear edges of a vane) of each first vane 511 (512, 513) and the axial line (AX) (as shown in FIG. 4), and a same second included angle (A2) is defined between a chord line (C2) of each second vane 521 (522, 523) and the axial line (AX) (as shown in FIG. 5). With reference to FIG. 7, a same third included angle (A3) is defined between a chord line (C3) of each third vane 531 (532, 533) and the axial line (AX). The first included angle (A1), the second included angle (A2) and the second included angle (A3) are unequal. In this preferred embodiment, preferably the first included angle (A1) is smaller than the third included angle (A3) and the third included angle is smaller than the second included angle (A2) (A1<A3<A2).

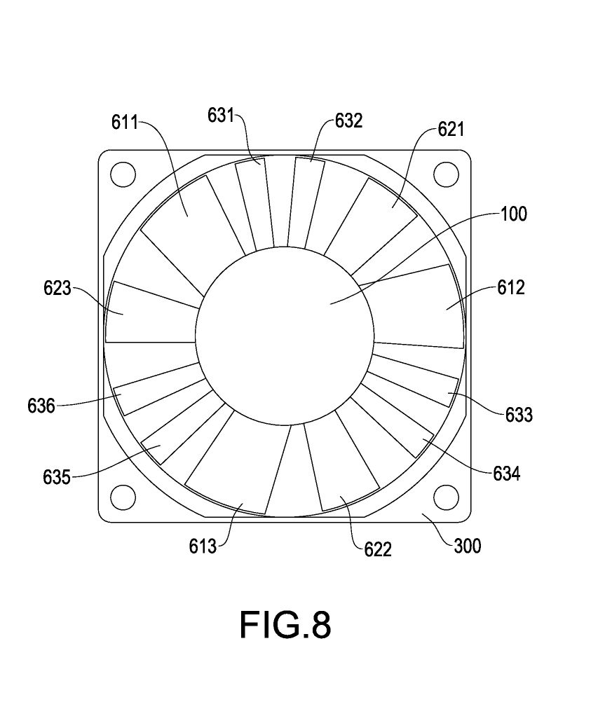

With reference to FIG. 8 for a heat dissipating fan in accordance with the third preferred embodiment of the present invention, the heat dissipating fan comprises a fan wheel, a drive motor (200), and a frame (300). The fan wheel comprises a fan hub (100), three first vanes (611, 612, 613), six second vanes (631, 632, 633, 634, 635, 636) and three third vanes (621, 622, 623). Wherein, the fan hub (100), the drive motor (200) and the frame (300) have the same structure and relation as those of the first preferred embodiment, and thus will not be repeated.

A same first included angle (A1) is defined between a chord line (C1) of each first vane 611 (612, 613) and the axial line (AX) (as shown in FIG. 4); and a same second included angle (A2) is defined between a chord line (C2) of each second vane 621 (622, 623, 624, 625, 626) and the axial line (AX) (as shown in FIG. 5); and a same is defined between a chord line (C3) of each third vane 631 (632, 633) and the axial line (AX) (as shown in FIG. 7).

In this preferred embodiment, the first vanes (611, 612, 613), the second vanes (631, 632, 633, 634, 635, 636) and the third vanes (621, 622, 623) have the same appearance, and are preferably integrally formed at the fan hub (100) and extended outwardly from the fan hub (100) and in a radial direction of the axial line (AX), and the first included angle (A1), the second included angle (A2) and the third included angle (A3) are unequal. Preferably, the first included angle (A1)<the third included angle (A3)<the second included angle (A2).

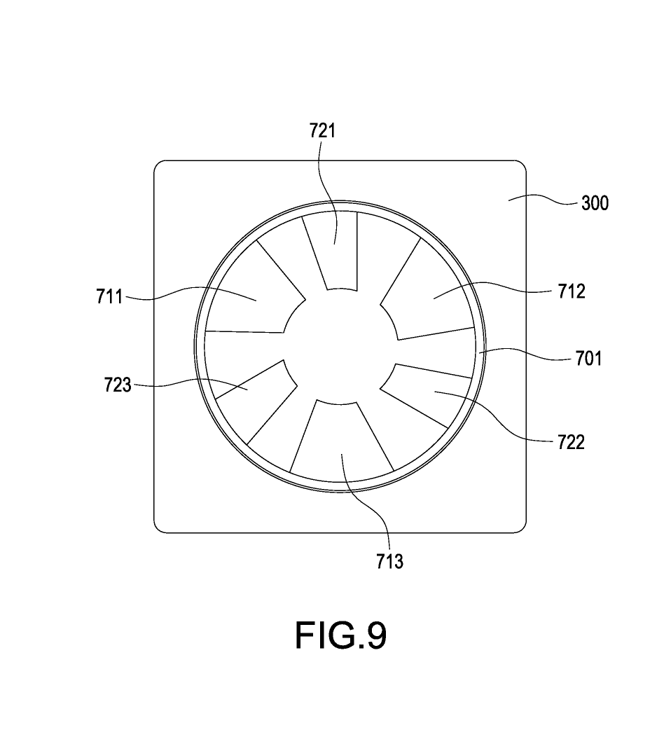

With reference to FIG. 9 for a schematic view of vanes installed in a fan wheel in accordance with the fourth preferred embodiment of the present invention, the heat dissipating fan comprises a fan wheel, a drive motor (200) and a frame (300). The fan wheel comprises three first vanes (711, 712, 713), three second vanes (721, 722, 723) and a connecting element (701).

A same first included angle (A1) is defined between a chord line (C1) of each first vane 711 (712, 713) and the axial line (AX) (as shown in FIG. 4); and a same second included angle (A2) is defined between a chord line (C2) of each second vane 721 (722, 723) and the axial line (AX) (as shown in FIG. 5).

In this preferred embodiment, the first vanes (711, 712, 713) and the second vanes (721, 722, 723) have the same appearance, and are extended outwardly from the axial line (AX) and in a radial direction of the axial line (AX), and external ends of the first vanes (711, 712, 713) and the second vanes (721, 722, 723) are connected by a connecting element (701), and the first included angle (A1) and the second included angle (A2) are unequal. Preferably the first included angle (A1) is smaller than the second included angle (A2).

When the heat dissipating fan and the fan wheel of the present invention are rotated, each vane of the fan wheel provides a different airflow and a different wind pressure, so that the best working efficiency of the vanes can be assured, no matter what is the flow impedance of the installing environment, so as to compensate the working efficiency of the remaining vanes. Therefore, the heat dissipating fan of the present invention can fit casings of different flow impedances.

While the invention has been described by means of specific embodiments, numerous modifications and variations could be made thereto by those skilled in the art without departing from the scope and spirit of the invention set forth in the claims.

What is claimed is:

1. A fan wheel, comprising:
an axial line (AX);
a radial line perpendicular to the axial line (AX);
a first vane (411, 412, 413, 511, 512, 513, 611, 612, 613, 711, 712 or 713), extended along the radial line;
a second vane (421, 422, 423, 521, 522, 523, 621, 622, 623, 624, 625, 626, 721, 722 or 723), extended along the radial line;
a first included angle (A1), defined between a chord line (C1) of the first vane (411, 412, 413, 511, 512, 513, 611, 612, 613, 711, 712 or 713) and the axial line (AX); and
a second included angle (A2), defined between a chord line (C2) of the second vane (421, 422, 423, 521, 522, 523, 621, 622, 623, 624, 625, 626, 721, 722 or 723) and the axial line (AX), and the second included angle (A2) and the first included angle (A1) being unequal angles.

2. The fan wheel of claim 1, further comprising a third vane (531, 532, 533, 631, 632 or 633) extended along the radial line, and a third included angle (A3) defined between a chord line (C3) of the third vane (531, 532, 533, 631, 632 or 633) and the axial line (AX), and the third included angle (A3), and the second included angle (A2) and the first included angle (A1) being unequal angles.

3. The fan wheel of claim 1, wherein there are a plurality of first vanes (411, 412, 413, 511, 512, 513, 611, 612, 613, 711, 712, 713) arranged uniformly in a circumferential direction of the axial line (AX).

4. The fan wheel of claim 1, wherein there are a plurality of second vanes (421, 422, 423, 521, 522, 523, 621, 622, 623, 624, 625, 626, 721, 722, 723) arranged uniformly in a circumferential direction of the axial line (AX).

5. A fan wheel, comprising:
a fan hub (100), having an axial line (AX) and a radial line perpendicular to the axial line (AX);
a first vane (411, 412, 413, 511, 512, 513, 611, 612 or 613), extended outwardly along the radial line from the periphery of the fan hub (100), and a first included angle (A1) being defined between a chord line (C1) of the first vane (411, 412, 413, 511, 512, 513, 611, 612 or 613) and the axial line (AX) of the fan hub (100); and
a second vane (421, 422, 423, 521, 522, 523, 621, 622, 623, 624, 625 or 626), extended outwardly along the radial line from the periphery of the fan hub (100), and a second included angle (A2) being defined between a chord line (C2) of the second vane (421, 422, 423, 521, 522, 523, 621, 622, 623, 624, 625 or 626) and the axial line (AX) of the fan hub (100), and the second included angle (A2) and the first included angle (A1) being unequal angles.

6. The fan wheel of claim 5, wherein there are a plurality of first vane (411, 412, 413, 511, 512, 513, 611, 612, 613) and a plurality of second vanes (421, 422, 423, 521, 522, 523, 621, 622, 623, 624, 625, 626) integrally formed at the fan hub (100).

7. The fan wheel of claim 5, further comprising a third vane (531, 532, 533, 631, 632 or 633) extended along the radial line and outwardly from the periphery of the fan hub (100), and a third included angle (A3) being defined between a chord line (C3) of the third vane (531, 532, 533, 631, 632 or 633) and the axial line (AX) of the fan hub (100), and the third included angle (A3), the second included angle (A2) and the first included angle (A1) being unequal angles.

8. A heat dissipating fan, comprising:
a fan hub (100), being a cylindrical body, and having an axial line (AX) and a radial line perpendicular to the axial line (AX);
a plurality of first vanes (411, 412, 413, 511, 512, 513, 611, 612, 613), extended along the radial line and outwardly from the periphery of the fan hub (100), and a first included angle (A1) being defined between a chord line (C1) of each of the first vanes (411, 412, 413, 511, 512, 513, 611, 612, 613) and the axial line (AX) of the fan hub (100); and
a plurality of second vanes (421, 422, 423, 521, 522, 523, 621, 622, 623, 624, 625, 626), extended along the radial line and outwardly from the periphery of the fan hub (100), and a second included angle (A2) being defined between a chord line (C2) of each of the second vanes (421, 422, 423, 521, 522, 523, 621, 622, 623, 624, 625, 626) and the axial line (AX) of the fan hub (100), and each of the second included angles (A2) and each of the first included angle (A1) being unequal angles.

9. The heat dissipating fan of claim 6, wherein the first vanes (411, 412, 413, 511, 512, 513, 611, 612, 613) are installed uniformly in a circumferential direction of the axial line (AX).

10. The heat dissipating fan of claim 8, wherein the second vanes (421, 422, 423, 521, 522, 523, 621, 622, 623, 624, 625, 626) are installed uniformly in a circumferential direction of the axial line (AX).

11. The heat dissipating fan of claim 8, wherein the first vanes (411, 412, 413, 511, 512, 513, 611, 612, 613) and the second vanes (421, 422, 423, 521, 522, 523, 621, 622, 623, 624, 625, 626) are integrally formed at the fan hub (100).

12. The heat dissipating fan of claim 8, further comprising a plurality of third vanes (531, 532, 533, 631, 632, 633) extended along the radial line and outwardly from the periphery of the fan hub (100), and a third included angle (A3) being defined between a chord line (C3) of each of the third vanes (531, 532, 533, 631, 632, 633) and the axial line (AX) of the fan hub (100), and each of the second included angles (A2), each of the first included angles (A1) and each of the second included angles (A2) being unequal angles.

13. The heat dissipating fan of claim 8, further comprising a frame (300), and the fan hub (100) being installed on an internal side of the frame (300).
